(19) United States
(12) Patent Application Publication
(10) Pub. No.: US 2023/0186551 A1
(43) Pub. Date: Jun. 15, 2023

(54) MULTI-MEDIUM IMAGING ANALYTIC METHOD FOR UNDERWATER MEDIUM SURFACE POSITION COMPENSATION

(71) Applicant: TONGJI UNIVERSITY, Shanghai (CN)

(72) Inventors: Xiaohua Tong, Shanghai (CN); Peng Chen, Shanghai (CN); Sa Gao, Shanghai (CN); Huan Xie, Shanghai (CN); Shijie Liu, Shanghai (CN); Yanmin Jin, Shanghai (CN); Yongjiu Feng, Shanghai (CN); Zhen Ye, Shanghai (CN); Sicong Liu, Shanghai (CN); Chao Wang, Shanghai (CN)

(73) Assignee: TONGJI UNIVERSITY, Shanghai (CN)

(21) Appl. No.: 17/722,400

(22) Filed: Apr. 18, 2022

(30) Foreign Application Priority Data
Dec. 14, 2021 (CN) 202110733603.2

(51) Int. Cl. G06T 15/20; G06F 17/11; G06F 17/16; G06T 7/30; G06T 5/00; G06T 5/50

(52) U.S. Cl. CPC G06T 15/20; G06F 17/11; G06F 17/16; G06T 5/006; G06T 5/50; G06T 7/30

(57) ABSTRACT

The present invention relates to a multi-medium imaging analytic method for underwater medium surface position compensation. The method is used for compensating a medium surface position based on refraction theorem, specifically comprising: acquiring a refractive index and a thickness of each medium, computing a medium surface position compensation value according to an incident angle, and obtaining a virtual medium surface as a new medium surface to convert a multi-medium imaging analysis model into a double-medium imaging analysis model. Compared with the prior art, the method has the advantages of high feasibility, excellent stability, sub-millimeter accuracy, and the like.

### CROSS-REFERENCE TO RELATED APPLICATION

This application claims the priority benefit of China application no. 202110733603.2, filed on Dec. 14, 2021. The entirety of the above-mentioned patent application is hereby incorporated by reference and made a part of this specification.

### FIELD OF TECHNOLOGY

The present invention relates to the field of underwater optical imaging, and in particular relates to a multi-medium imaging analytic method for underwater medium surface position compensation.

### BACKGROUND

Compared with a traditional optical geometry analytic method, in underwater vision measurement, an imaging equation no longer meets the traditional collinearity equations (Kotowksi, 1988) due to refractive projections of different media, thus a multi-medium imaging analytic algorithm has become the most important space geometry analytic algorithm, analytic accuracy and computation complexity of which directly influence quality of measurement results and computational efficiency.

At present, the research on the application of underwater vision measurement is mainly focused on the field of computer vision, most of research results are only for simple double-medium imaging analysis, and are only in the simplified refraction geometry model for the multi-medium imaging analysis; the actual optical imaging model is considered too idealized, for example, ideal model conditions that an image plane is parallel to the medium surface, the thickness of the intermediate medium is ignored, and coefficient of refraction of the medium is known are set.

However, in practical engineering application, the ideal imaging model has low underwater target localization accuracy due to the neglect of some parameters in a precise analytic model, thus most of the previous research results can only be applied to underwater 3D reconstruction tasks with low accuracy requirements and cannot be directly applied to precision measurements of underwater structures with millimeter-level accuracy.

### SUMMARY

An objective of the present invention is to provide a multi-medium imaging analytic method for underwater medium surface position compensation to overcome defects in the prior art.

The objective of the present invention can be achieved through the following technical solutions:

a multi-medium imaging analytic method for underwater medium surface position compensation is used for compensating a medium surface position based on refraction theorem, specifically comprising:

acquiring a refractive index and a thickness of each medium, computing a medium surface position compensation value according to an incident angle, and obtaining a virtual medium surface as a new medium surface to convert a multi-medium imaging analysis model into a double-medium imaging analysis model.

A corresponding relationship between an incident angle and an emergent angle at each medium surface is acquired according to the Snell’s Law, and a relationship among the incident angle, the emergent angle, the medium surface position compensation value and the medium thickness is obtained according to the sine theorem and the trigonometric function relationship.

When media along an incident direction are air, glass, and water in sequence, a computational formula of the medium surface position compensation value is as follows:

$$d l = \frac{d ⋅ sin \left(π - {θ}_{1} + {θ}_{2}\right) ⋅ cos {θ}_{3}}{sin \left({θ}_{1} - {θ}_{3}\right) ⋅ cos {θ}_{2}} - d$$

wherein dl is the medium surface position compensation value, i.e., a distance between a virtual medium surface and an air-glass medium surface, d is a thickness of the glass, θ₁ is an incident angle of the air-glass medium surface, θ₂ is an emergent angle of the air-glass medium surface, and θ₃ is an emergent angle of a glass-water medium surface.

An equation for obtaining a virtual medium surface according to the medium surface position compensation value is as follows:

$$A X + Y + B Z + C - d l \times \sqrt{\left({A}^{2} + 1 + {B}^{2}\right)} = 0$$

wherein A, B and C are respectively equation coefficients of the virtual medium surface.

The medium surface position compensation value is only related to an incident angle and the medium thickness, and for a multilayer medium, a lookup table is constructed according to a medium type and the medium thickness.

For a situation where incident angles of target points are inconsistent in the processing of mass high-speed image sequences, linear interpolation or cubic convolution interpolation is conducted on the constructed lookup table to make each target point have a corresponding medium surface position compensation value.

The accuracy of the underwater point measurement of the method reaches a sub-millimeter level.

In a similar way, for a multi-medium model, computation is conducted according to a derivation method of three layers of media.

Compared with the prior art, the present invention has the following advantages:

in accordance with a multi-medium imaging analytic method for underwater medium surface position compensation provided by the present invention, three-dimensional space coordinates and three-dimensional deformation parameters of an underwater target are accurately measured, and stability of the multi-medium imaging analytic method is verified through simulation tests. Experimental results indicate that the method can achieve sub-millimeter level point position measurement accuracy in the precision measurement of underwater structures.

### BRIEF DESCRIPTION OF THE DRAWINGS

FIG. 1A is an existing three-medium imaging geometrical relationship.

FIG. 1B is a double-medium imaging geometrical relationship based on medium surface position compensation.

FIG. 2A-FIG. 2B is a medium surface position compensation lookup table, wherein FIG. 2A is a two-dimensional display, and FIG. 2B is a three-dimensional display.

FIG. 3A-FIG. 3D is simulation data of different parameters in a simulation process, wherein FIG. 3A is image coordinate error simulation distribution as σ_{ic} = 0.1 pixels, FIG. 3B is object space coordinate error simulation distribution as σ_{oc} = 0.5 mm, FIG. 3C is medium surface position error simulation distribution as σₘₛ = 0.5 mm, and FIG. 3D is refractive index error simulation distribution as σᵣᵢ = 0.0001.

FIG. 4A-FIG. 4D is accuracy evaluation under simulation errors of different types of parameters, wherein FIG. 4A is a point position root-mean-square error curve over 1000 simulation tests as σ_{ic}= 0.1 pixels, FIG. 4B is a point position root-mean-square error curve over 1000 simulation tests as σ_{oc} = 0.5 mm, FIG. 4C is a point position root-mean-square error curve over 1000 simulation tests as σₘₛ = 0.5 mm, and FIG. 4D is a point position root-mean-square error curve over 1000 simulation tests as σᵣᵢ = 0.0001.

FIG. 5A-FIG. 5D is overall accuracy evaluation, wherein FIG. 5A is an overall point root-mean-square error curve for check point coordinates as σ_{ic} is increased from 0.01 pixels to 0.1 pixels, FIG. 5B is an overall point root-mean-square error curve for check point coordinates as σ_{oc} is increased from 0.1 mm to 1 mm, FIG. 5C is an overall point root-mean-square error curve for check point coordinates as σₘₛ is increased from 0.1 mm to 1 mm, and FIG. 5D is an overall point root-mean-square error curve for check point coordinates as σᵣᵢ is increased from 0.00005 to 0.00015.

FIG. 6A-FIG. 6B is accuracy evaluation of a check point under single-medium imaging analysis, double-medium imaging analysis, and three-medium imaging analysis, wherein FIG. 6A is a comparison of a single-medium imaging analytic method and a three-medium imaging analytic method, and FIG. 6B is a comparison of a double-medium imaging analytic method and a three-medium imaging analytic method.

FIG. 7 is influence of a thickness of an intermediate medium on the overall measurement error.

### DESCRIPTION OF THE EMBODIMENTS

The present invention is described in detail below with reference to the accompanying drawings and specific embodiments.

### Embodiment

The present invention provides a multi-medium imaging analytic method for underwater medium surface position compensation, wherein the method is used for compensating a medium surface position based on refraction theorem to convert a multi-medium imaging analytic model into a simple double-medium imaging analytic model. In the process of simplification, a strict medium surface compensation equation is derived through a ray tracing method. For better understanding, the classical multi-medium photogrammetry problem “air-glass-water” model is used to explain the mathematical conversion process in the multi-media imaging analytical model in the embodiment, assuming that medium surfaces are parallel to each other, then the mathematical conversion from multi-medium to double-medium is achieved.

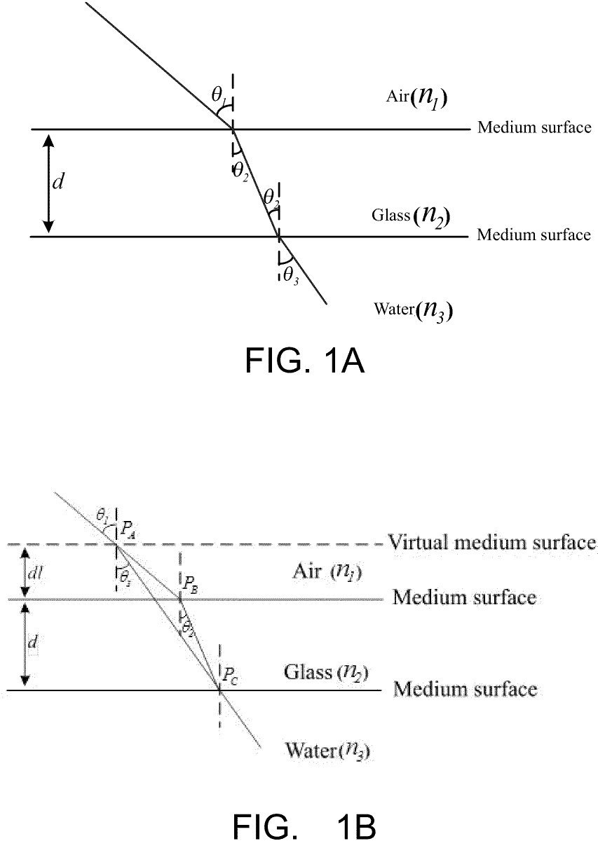

As shown in FIG. 1A, a relationship between an incident angle and a refraction angle is acquired through Snell’s law:

$$\left\{\begin{matrix}\frac{{n}_{1}}{{n}_{2}} = \frac{sin {θ}_{2}}{sin {θ}_{1}} \\ \frac{{n}_{2}}{{n}_{3}} = \frac{sin {θ}_{3}}{sin {θ}_{2}} \\ \frac{{n}_{1}}{{n}_{3}} = \frac{sin {θ}_{3}}{sin {θ}_{1}}\end{matrix}\right)$$

in above equation, n₁ , n₂ and n₃ respectively denote refractive index parameters of air, glass, and water; and when the incident angle and the refractive index parameter of the medium are known, the refraction angle can be computed according to the equation (1).

As shown in FIG. 1B, in the triangle ΔP_{A}P_{B}P_{C} :

$${l}_{{P}_{B} {P}_{C}} = d / cos {θ}_{2}$$

in the equation (2), lP_{B}P_{C} denotes the length of a line segment between an end point P_{B} and an end point P_{C}, and meanwhile, the following angle relationship can be acquired from FIG. 1B:

$$\left\{\begin{matrix}∠ {P}_{B} {P}_{A} {P}_{C} = {θ}_{1} - {θ}_{3} \\ ∠ {P}_{A} {P}_{B} {P}_{C} = π - {θ}_{1} + {θ}_{2}\end{matrix}\right)$$

in the equation (3), ∠P_{B}P_{A}P_{C} denotes an included angle between a line segment P_{B}P_{A} and a line segment P_{A}P_{C}, ∠P_{A}P_{B}P_{C} denotes an included angle between a line segment P_{A}P_{B} and a line segment P_{B}P_{C}. The following can be obtained from the sine theorem:

$$\frac{{l}_{{P}_{B} {P}_{C}}}{sin ∠ {P}_{B} {P}_{A} {P}_{C}} = \frac{{l}_{{P}_{A} {P}_{C}}}{sin ∠ {P}_{A} {P}_{B} {P}_{C}}$$

in the equation (4), lP_{A}P_{C} denotes the length of a line segment between an end point P_{A} and the end point P_{C}, and based on the equation (4), the following can be obtained:

$${l}_{{P}_{A} {P}_{C}} = \frac{{l}_{{P}_{B} {P}_{C}} ⋅ sin ∠ {P}_{A} {P}_{B} {P}_{C}}{sin ∠ {P}_{B} {P}_{A} {P}_{C}} = \frac{d ⋅ sin \left(π - {θ}_{1} + {θ}_{2}\right)}{sin \left({θ}_{1} - {θ}_{3}\right) ⋅ cos {θ}_{2}}$$

In addition, the following can be obtained according to the trigonometric function relationship:

$$d + d l = {l}_{{P}_{A} {P}_{c}} ⋅ cos {θ}_{3}$$

Based on the equation (5) and the equation (6), a medium surface position compensation value dl can be obtained:

$$d l = \frac{d ⋅ sin \left(π - {θ}_{1} + {θ}_{2}\right) ⋅ cos {θ}_{3}}{sin \left({θ}_{1} - {θ}_{3}\right) ⋅ cos {θ}_{2}} - d$$

in the double-medium imaging model, the compensation value dl can directly correct a medium surface position parameter, as shown in FIG. 1B, the compensation value dl can be regarded as amount of movement of the medium surface along a normal direction. Therefore, an equation of a virtual medium surface can be derived based on the medium plane space equation, specifically as follows:

$$A X + Y + B Z + C - d l \times \sqrt{\left({A}^{2} + 1 + {B}^{2}\right)} = 0$$

Refractive index parameters n₁, n₂ and n₃ of three media can be measured through a high-accuracy refractometer, therefore, the compensation value (dl) of the medium surface is only determined by the incident angle (θ₁) and the thickness (d) of the glass medium. When a spatial position of the medium surface is known, a spatial position of the virtual medium surface can be derived, and then the virtual medium surface is used as a new medium surface to simplify a refraction model, and a multi-medium geometry analytic problem can be converted into the ordinary double-medium geometry analytic problem through the computation of the virtual medium surface. Hence, according to the Snell’s law and the law of rectilinear propagation of light, when the light passes through different numbers of media or different types of media, a geometric shape of light path propagation can be determined to be derived to the virtual medium surface. To solve the problem of complex multi-medium imaging analysis, a multi-medium imaging analytic method is simplified to a double-medium imaging analytic method through a medium surface position compensation mode.

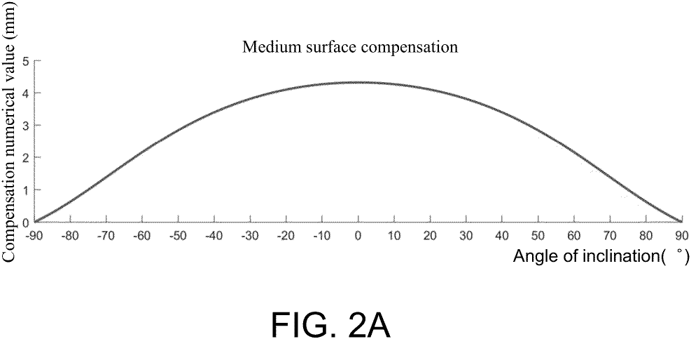

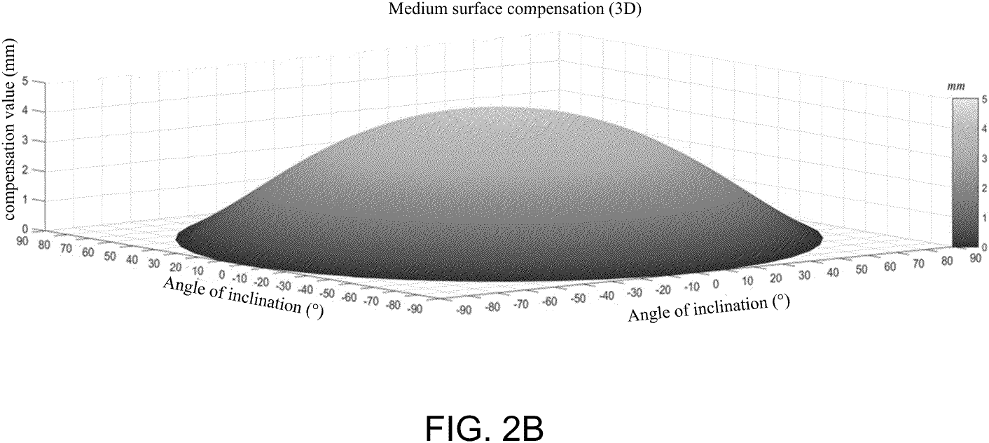

Based on the equation (8), the medium surface position compensation values under different incident angle conditions can be computed under the condition that the thickness of medium is known. For example, when d is 11.9 mm, compensation values computed according to different incident angles are as shown in FIG. 2A-FIG. 2B; in imaging analysis of more layers of media, when the refractive indexes and the thicknesses of all media are known, a position of the virtual medium surface can still be derived by using a similar ray tracing method. In the specific engineering application, a lookup table can be constructed according to predefined medium types and medium thicknesses to accelerate the computational efficiency. In the processing of mass high-speed image sequences, the incident angles of all target points are inconsistent due to difference of image positions, so that each target tracking point position has an own medium surface position compensation value. As shown in FIG. 2A-FIG. 2B, if the lookup table is generated with sufficient division density, the medium surface position compensation value of each target point can be easily and directly provided through a data interpolation method. In addition, the linear interpolation or cubic convolution interpolation has been able to meet experiment demands in a computational method based on the lookup table.

### Simulation Experiment and Analysis

To verify feasibility and stability of the method provided by the present invention, a simulation test of the multi-medium imaging geometry analysis is implemented based on a Monte Carlo analog simulation method. In the experiment, when errors of different levels are added in the image point coordinates, the object space point coordinates, the medium surface position parameter and the refractive index parameter, the stability of the method is respectively tested. The Monte Carlo simulation method can be used to analyze the uncertainty and random distribution of each model parameter and the influence of the model parameters on the entire photogrammetric geometric model. The simulation test is mainly focused on the influence of different types of parameter errors on positioning results of the point positions. A computational equation of simulation data is as follows:

$${p}_{r} = {p}_{o} + {σ}_{p} * n G a u s s$$

In the equation (9), Pᵣ is an output simulation parameter, Pₒ is an input original parameter, σₚ is a standard deviation (error) of the simulation parameter, and nGauss is a random parameter of normal distribution (Gaussian distribution). In an iterative optimization process of the multi-medium imaging analytic model, a certain set of input parameters may directly influence the calculation of other parameters. To analyze and compare the influence of different types of parameters on the three-dimensional reconstruction, an analog simulation result is evaluated by using the reconstruction accuracy of the check point in this experiment.

Before the simulation test, an error-free photogrammetric network needs to be constructed through the multi-medium imaging geometric model. To simulate the construction of the multi-medium photogrammetric network, a true three-dimensional multi-medium photogrammetric network can be directly converted into the error-free photogrammetric network in a way of ignoring the parameter error. Therefore, the simulation parameters in the multi-medium photogrammetric network are as shown in Table 1.

Table 1 Simulation parameters including camera parameters, refractive index parameters, and medium surface position parameters

Camera parameter

| | f (pixel) | Xs (m) | Ys (m) | Zs (m) | φ (°) | ω (°) | κ (°) |
|---|---|---|---|---|---|---|---|
| Left camera | 1471.898 | 4.8842 | 2.9283 | 2.4929 | -14.6783 | 78.1596 | -4.8056 |
| Right camera | 1481.321 | 5.5344 | 2.9514 | 2.4687 | 11.2865 | 80.0817 | 0.4145 |
| | Refractive index | | | Medium surface position parameter | | | |
| | n (air) | n (glass) | n (water) | RA | RB | RC | RD (m) |
| | 1.0 | 1.5 | 1.333 | 0 | 1 | 0 | -3.5 |

Control point coordinates are randomly generated in a field of view of about 2 m of the camera; in accordance with the simulation parameters in the Table 1, the image coordinates of these control points can be computed through a back projection method based on the multi-medium imaging analytic model, and then the error-free multi-medium photogrammetric network is constructed. In addition, the simulated control points are divided into two parts, one of which is involved in the computation of multi-medium bundle adjustment and the other is considered as a check point for three-dimensional accuracy evaluation, thus verifying the robustness of the multi-medium imaging analytic method for underwater medium surface position compensation. In the simulation test, 20 control points are involved in the computation of the multi-medium bundle adjustment, and the other 20 control points are considered as check data.

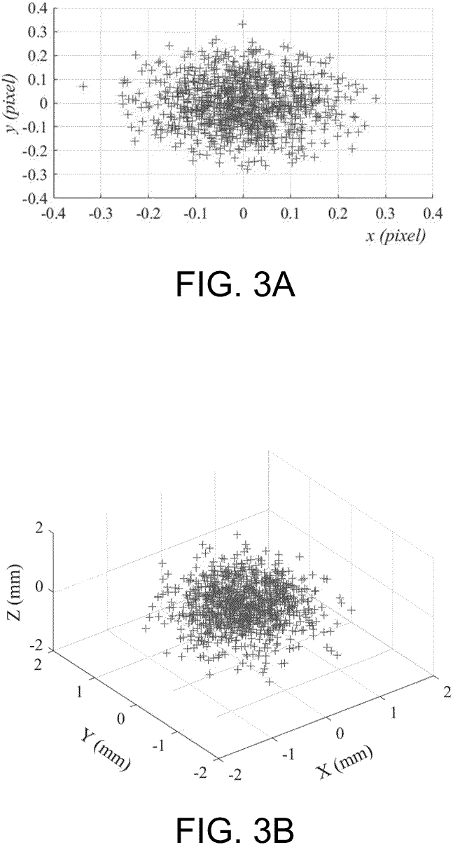

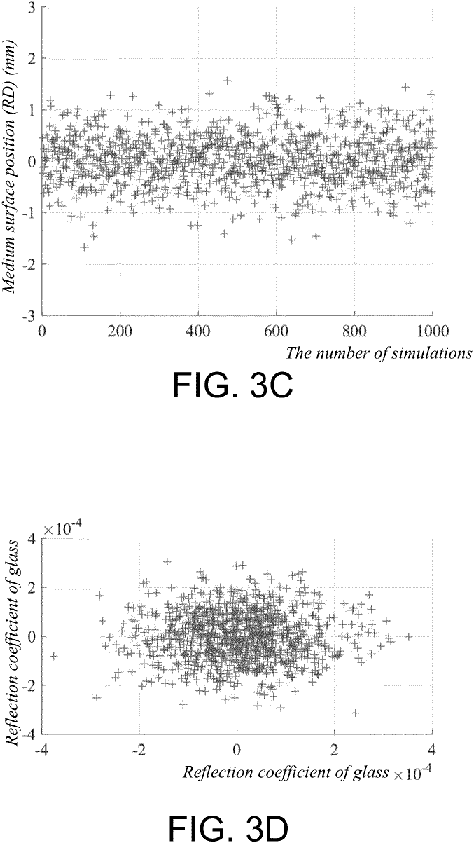

In the simulation experiment, the influences of the image coordinate error, the object space coordinate error, the medium surface position error, and the refractive index error on the three-dimensional reconstruction accuracy are respectively calculated and analyzed. In consideration of an identifying accuracy of a round target, the image coordinate error σ_{ic} is simulated between 0.01 pixel and 0.1 pixel; according to the point position measurement accuracy of a total station, the object pace coordinate error σ_{oc} is simulated between 0.1 mm and 1 mm; similarly, the medium surface position error σₘₛ is also set between 0.1 mm and 1 mm; and according to the measurement accuracy of an abbe refractometer, the simulation error σᵣᵢ of the refractive rate is between 0.00005 and 0.00015. As shown in FIGS. 3A-3D, 1000 analog simulation values of four sets of parameters of different types are generated based on the equation (9).

Table 2 Coordinate difference between computed value and simulated (true) value of check point

| Point numb er | Coordinate difference | | | Point numb er | Coordinate difference | | |
|---|---|---|---|---|---|---|---|
| | ΔX(m m) | ΔY(m m) | ΔZ(m m) | | ΔX(m m) | ΔY(m m) | ΔZ(m m) |
| 1 | 0.07 | 0.50 | -0.32 | 11 | -0.21 | 1.11 | 0.29 |
| 2 | 0.01 | 0.75 | 0.08 | 12 | -0.01 | 0.18 | 0.04 |
| 3 | -0.05 | -0.03 | 0.02 | 13 | -0.11 | 0.38 | -0.03 |
| 4 | -0.13 | 0.77 | 0.17 | 14 | 0.16 | 0.75 | -0.13 |
| 5 | -0.19 | 1.07 | -0.68 | 15 | -0.01 | 0.26 | -0.15 |
| 6 | -0.07 | 0.39 | 0.30 | 16 | 0.05 | -0.07 | -0.02 |
| 7 | -0.09 | -0.73 | 0.43 | 17 | -0.27 | -1.87 | 0.76 |
| 8 | -0.14 | 0.07 | -0.02 | 18 | 0.02 | 0.01 | 0.02 |
| 9 | 0.05 | 0.31 | 0.09 | 19 | 0.20 | 0.85 | -0.49 |
| 10 | 0.09 | 0.13 | -0.21 | 20 | 0.40 | -0.56 | 0.10 |
| | | | | RMS | 0.15 | 0.70 | 0.31 |

In each simulation computation, all model parameters are recomputed through a multi-medium bundle adjustment method, and then object space coordinates of the check point are reconstructed through a forward intersection algorithm. Therefore, a coordinate difference between a calculated value and a simulated (true) value in the method of the present invention is regarded as an accuracy evaluation index. When the Gaussian random error of 0.1 pixels is introduced into the image coordinates, the comparison results of the calculated values and the simulated values of the check points are shown in detail in table 2. For 20 check points, the coordinate root-mean-square (RMS) errors

$$\left({Δ}_{R x , R y o r R z} = \sqrt{{\sum }_{1}^{n} {Δ}_{X , Y o r Z}^{2} / n}\right)$$

thereof may reach 0.15 mm in an X direction, may reach 0.7 mm in a Y direction, and may reach 0.31 mm in a^{z} direction; and the overall positioning error

$$\left({Δ}_{R t} = \sqrt{{Δ}_{R x} {}^{2} + {Δ}_{R y} {}^{2} + {Δ}_{R z} {}^{2}}\right)$$

may reach 0.78 mm. Therefore, under the multi-medium photogrammetric network simulated this time, an image coordinate error of 0.1 pixel may cause a point position three-dimensional reconstruction error of about 0.78 mm.

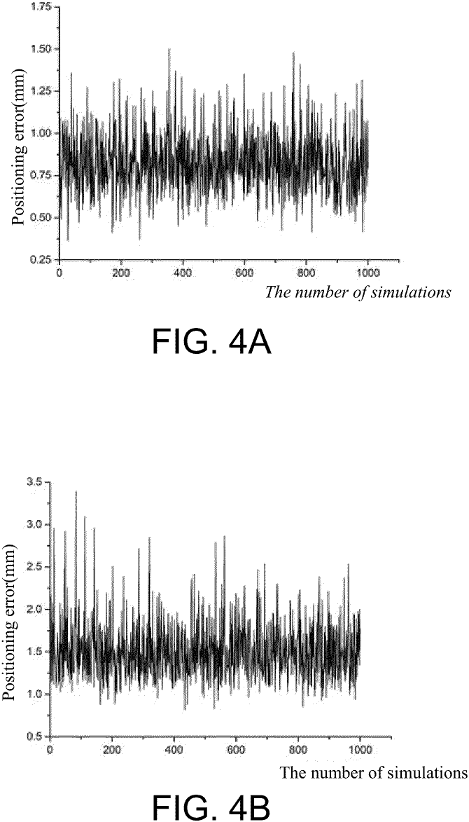

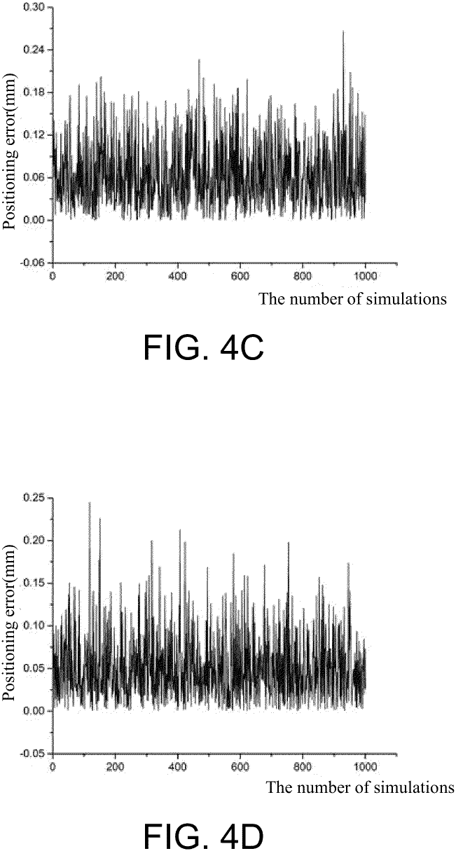

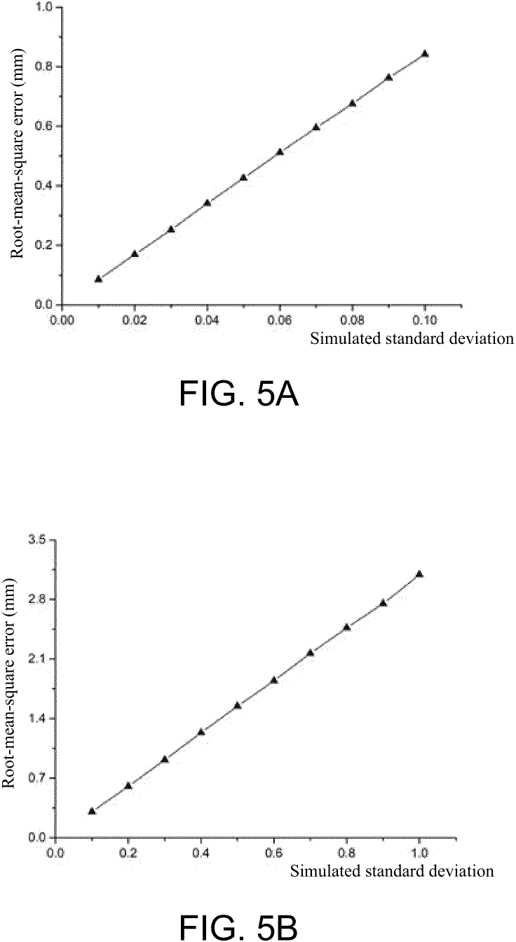

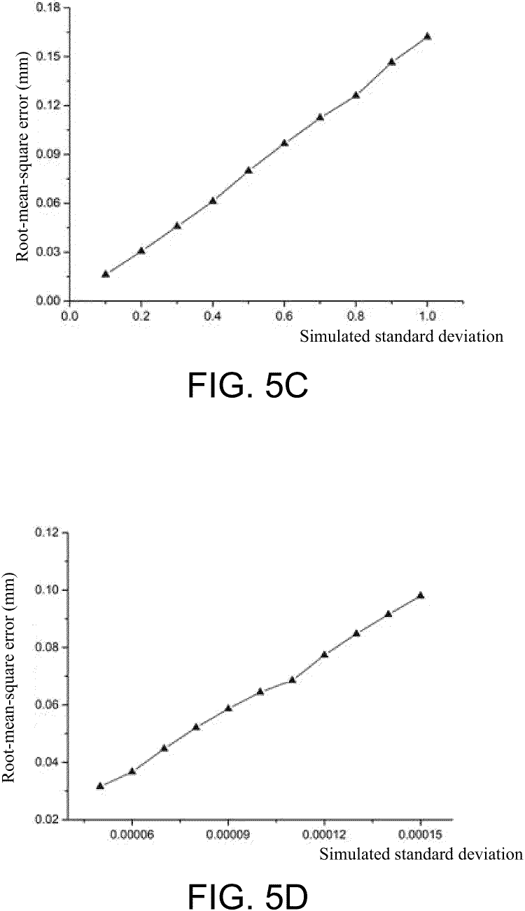

FIG. 4A illustrates a point position root-mean-square error curve caused by the image coordinate error of 0.1 pixel over 1000 simulation tests. Similarly, FIG. 4B-FIG. 4D illustrate point position root-mean-square error curves of different types of parameter errors (σ_{oc} = 0.5 mm, σₘₛ = 0.5 mm and σᵣᵢ = 0.0001) over 1000 simulation tests. It can be known from the figure that the image coordinate error and the object space coordinate error of the control point position may make a greater influence on the three-dimensional accuracy of a target point. As shown in FIG. 5B-FIG. 5D, as errors of different magnitudes are introduced into the simulated multi-medium photogrammetric model, the overall root-mean-square

$$\left({σ}_{R t} = \sqrt{{\sum }_{1}^{n} {Δ}_{R t} {}^{2} / n ,} n = 1000\right)$$

of the check point coordinates is clearly displayed. Obviously, the three-dimensional reconstruction error of the measured point position is increased as the model parameter error increases.

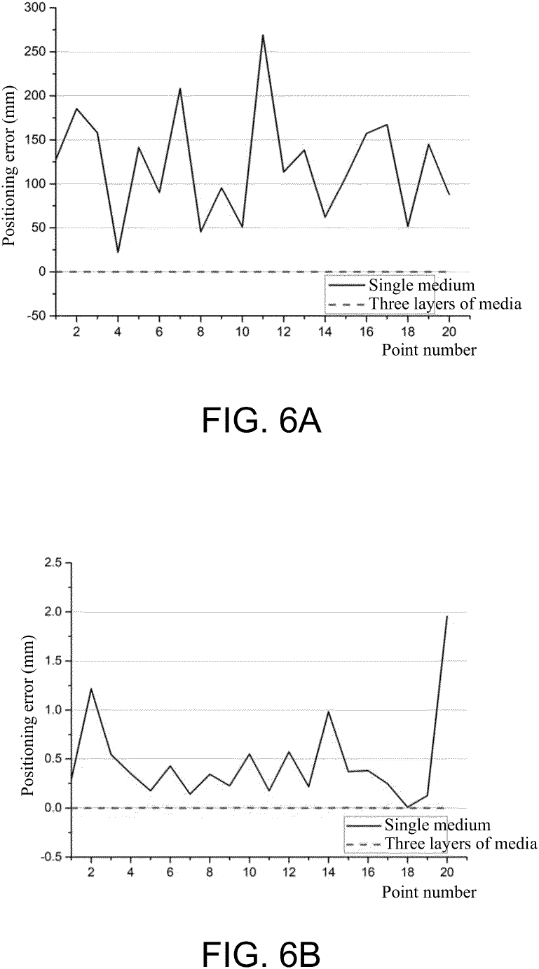

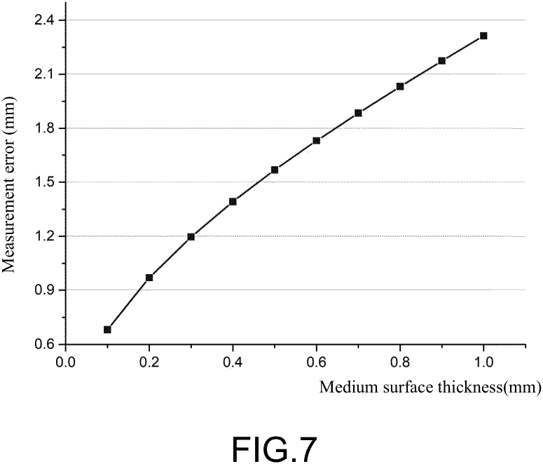

As shown in FIG. 6A-FIG. 6B, to further verify the accuracy of the multi-medium imaging analytic algorithm, the three-dimensional reconstruction accuracies of the single-medium imaging analytic algorithm, the double-medium imaging analytic algorithm and the multi-medium imaging analytic algorithm are respectively compared and analyzed. The extremely severe three-dimensional error is caused due to the neglect of refractive geometric relationship of the light in the single-medium imaging analytic algorithm. Relatively less three-dimensional positioning error is similarly caused due to the neglect of thickness of an intermediate medium (e.g., glass) in the double-medium imaging analytic algorithm. Wherein the influence of the thickness of the intermediate medium on the positioning accuracy of the three-dimensional point position is as shown in FIG. 7, the point position measurement error is increased as the thickness of the intermediate medium increases. Therefore, in the precise underwater target measurement, a strict photogrammetric geometric model should be followed to solve the problem, and the importance of a multi-medium imaging analytic algorithm is more verified through the comparative analysis. Moreover, the sub-millimeter level underwater point position measurement accuracy can be achieved through the multi-medium imaging analytic method for underwater medium surface position compensation provided by the present invention.

What is claimed is:

1. A multi-medium imaging analytic method for underwater medium surface position compensation, wherein the multi-medium imaging analytic method is used for compensating a medium surface position based on refraction theorem, specifically comprising:
acquiring a refractive index and a thickness of each medium, computing a medium surface position compensation value according to an incident angle, and obtaining a virtual medium surface as a new medium surface to convert a multi-medium imaging analysis model into a double-medium imaging analysis model.

2. The multi-medium imaging analytic method for underwater medium surface position compensation according to claim 1, wherein a corresponding relationship between an incident angle and an emergent angle at each medium surface is acquired according to the Snell’s Law, and a relationship among the incident angle, the emergent angle, the medium surface position compensation value and a medium thickness is obtained according to a sine theorem and a trigonometric function relationship.

3. The multi-medium imaging analytic method for underwater medium surface position compensation according to claim 2, wherein, when media along an incident direction are air, glass, and water in sequence, a computational formula of the medium surface position compensation value is as follows:
$$d l = \frac{d ⋅ sin \left(π - {θ}_{1} + {θ}_{2}\right) ⋅ cos {θ}_{3}}{sin \left({θ}_{1} - {θ}_{3}\right) ⋅ cos {θ}_{2}} - d$$
wherein ^{dl} is the medium surface position compensation value, i.e., a distance between the virtual medium surface and an air-glass medium surface, ^{d} is a thickness of the glass,
$${θ}_{{1}_{\text{is}}}$$
an incident angle of the air-glass medium surface,
$${θ}_{{2}_{\text{is}}}$$
an emergent angle of the air-glass medium surface, and
$${θ}_{{3}_{\text{is}}}$$
an emergent angle of a glass-water medium surface.

4. The multi-medium imaging analytic method for underwater medium surface position compensation according to claim 3, wherein an equation for obtaining the virtual medium surface according to the medium surface position compensation value is as follows:
$$A X + Y + B Z + C - d l \times \sqrt{\left({A}^{2} + 1 + {B}^{2}\right)} = 0$$
wherein ^{A}, ^{B} and ^{C} are respectively equation coefficients of the virtual medium surface.

5. The multi-medium imaging analytic method for underwater medium surface position compensation according to claim 1, wherein the medium surface position compensation value is only related to the incident angle and a medium thickness, and for a multilayer medium, a lookup table is constructed according to a medium type and the medium thickness.

6. The multi-medium imaging analytic method for underwater medium surface position compensation according to claim 5, wherein for a situation wherein incident angles of target points are inconsistent in the processing of mass high-speed image sequences, a linear interpolation or a cubic convolution interpolation is conducted on the constructed lookup table to make each target point have a corresponding medium surface position compensation value.

7. The multi-medium imaging analytic method for underwater medium surface position compensation according to claim 1, wherein an accuracy of the multi-medium imaging analytic method reaches a sub-millimeter level.
